(19) United States
(12) Patent Application Publication
(10) Pub. No.: US 2026/0206188 A1
(43) Pub. Date: Jul. 16, 2026

(54) SNAP-IN CONNECTOR, HEAT EXCHANGER WITH A SNAP-IN CONNECTOR AND COOLING SYSTEM

(71) Applicant: Infineon Technologies Austria AG, Villach (AT)

(72) Inventors: Uwe KIRCHNER, Witra (AT); Anton MAUDER, Kolbermoor (DE); Robert RÖSNER, Oberschleißheim (DE); Richard KNIPPER, Regensburg (DE)

(21) Appl. No.: 19/418,534

(22) Filed: Dec. 12, 2025

(30) Foreign Application Priority Data
Jan. 10, 2025 (DE) 102025100706.3

(51) Int. Cl. H05K 7/20; H10W 40/20

(52) U.S. Cl. CPC H05K 7/20645; H10W 40/235

(57) ABSTRACT

A snap-in connector includes a body having a radial-symmetric inserting portion and a base portion. A first circumferential groove is arranged at the inserting portion spaced apart from the base portion in an inserting direction of the connector. The inserting portion includes an end portion spaced apart from the first circumferential groove in the inserting direction. A second circumferential groove is arranged at the inserting portion between the end portion and the first circumferential groove. The snap-in connector further includes a first gasket arranged in the first groove configured to seal-up in a radial direction, and a radial symmetric locking spring accommodated in the second groove.

### CROSS-REFERENCE TO RELATED APPLICATION

This application claims priority to Germany Patent Application No. 102025100706.3 filed on Jan. 10, 2025, the content of which is incorporated by reference herein in its entirety.

### TECHNICAL FIELD

The present disclosure relates to a snap-in connector, comprising a body, the body comprising a radial-symmetric inserting portion and a base portion. The disclosure further relates to a heat exchanger comprising the snap-in connector and to a cooling system comprising the heat exchanger.

### BACKGROUND

In high power applications liquid cooling is the cooling method to transfer the heat to a cooling element. The existing liquid cooled systems are complex combined with a complex assembly of, for example, their fittings and sealing elements.

It is therefore desirable to lower the effort of the assembly.

### SUMMARY

According to a first aspect of the present disclosure, a snap-in connector is of the aforementioned kind is provided, wherein a first circumferential groove is arranged at the inserting portion spaced apart from the base portion in an inserting direction of the connector,
wherein the inserting portion includes an end portion spaced apart from the first circumferential groove in the inserting direction, wherein a second circumferential groove is arranged at the inserting portion between the end portion and the first circumferential groove, and wherein the snap-in connector further includes a first gasket arranged in the first groove configured to seal-up in a radial direction, and a radial symmetric locking spring accommodated in the second groove.

A modular cooling setup is provided, where fast assembly is ensured by premade building blocks which are connected via a permanent snap-in connection system. This non-releasable snap-in connection is provided by the above snap-in connector and ensures proper sealing whilst not relying on complex assemblies like gluing or torque-based sealing via screws/clamps. The snap-in connector of the present disclosure typically features same lifetime as components being assembled. This removes a need for maintenance of cooling-circuit components. The diameter of the snap-in connector can be adjusted to the requirements, e. g. a connector providing liquid cooling to only a limited number of power devices can have a smaller cross section for liquid line than a connector supplying a power electronic system.

Whilst ensuring a sealed, liquid tight connection, the flexible spring-loaded nature of the connection prevents excessive transfer of mechanical loads from sub-assemblies (which are at elevated uneven temperatures) from a main supply backbone (at constant lower temperatures). A non-releasable connection may combine both aspects (seal+decouple) into one assembly.

According to a second aspect of the disclosure, a heat exchanger is provided, the heat exchanger, including a snap-in connector including a base portion and an inserting portion, wherein the base portion is configured to be thermally coupled to a heat source and the inserting portion is configured to interlock with a corresponding opening, wherein the inserting portion includes an end portion at a distal end of the snap-in connector in an inserting direction, and a heat exchanger portion configured to transfer heat to a fluid, wherein the heat exchanger portion is coupled to the end portion of the snap-in connector.

The snap-in connector may be the snap-in connector formed according to the first aspect.

The heat exchanger according to the second aspect enables to directly connect a single discrete electric device to a reservoir of a cooling medium by providing a self-sealing snap-in connection, which can be applied to a discrete device.

The heat exchanger is capable of sealing itself into a cooling channel via a non-removable connection.

According to a third aspect of the disclosure a cooling system for cooling an electronic device is provided, the system including the snap-in connector of the first aspect wherein both the inserting portion and the base portion surround a fluid channel, the fluid channel extending along and being concentric with an axis of radial symmetry of the body, and a fluid pipe including at least one sidewall with an opening to which the snap-in connector is attachable.

### BRIEF DESCRIPTION OF THE DRAWINGS

Example implementations of the disclosure are described with reference to the following figures:

FIG. 1 shows an extended view of a schematic snap-in connector according to the first aspect of the disclosure.

FIG. 2 shows a schematic view connector before being inserted into an opening of a tube or housing.

FIG. 3 shows a schematic view of a connector of FIG. 2 being inserted into the opening of the tube or housing in an inserted position.

FIG. 4 shows a schematic view of a heat exchanger according to the second aspect of the disclosure together with various possible arrangements of the protrusions or cooling fins.

FIG. 5 shows the heat exchanger of FIG. 4 in a mounted position.

FIG. 6 shows a cross section of the heat exchanger of FIG. 5 in an inserted position.

FIG. 7 shows a further implementation of the heat exchanger according to the second aspect of the disclosure.

FIG. 8 shows a cross-sectional view of the heat exchanger of FIG. 7.

FIG. 9 shows the part of a cooling system comprising the snap in connector according to the disclosure.

### DETAILED DESCRIPTION

In the following detailed description, reference is made to the accompanying drawings. The drawings show specific examples in which the implementation may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”.

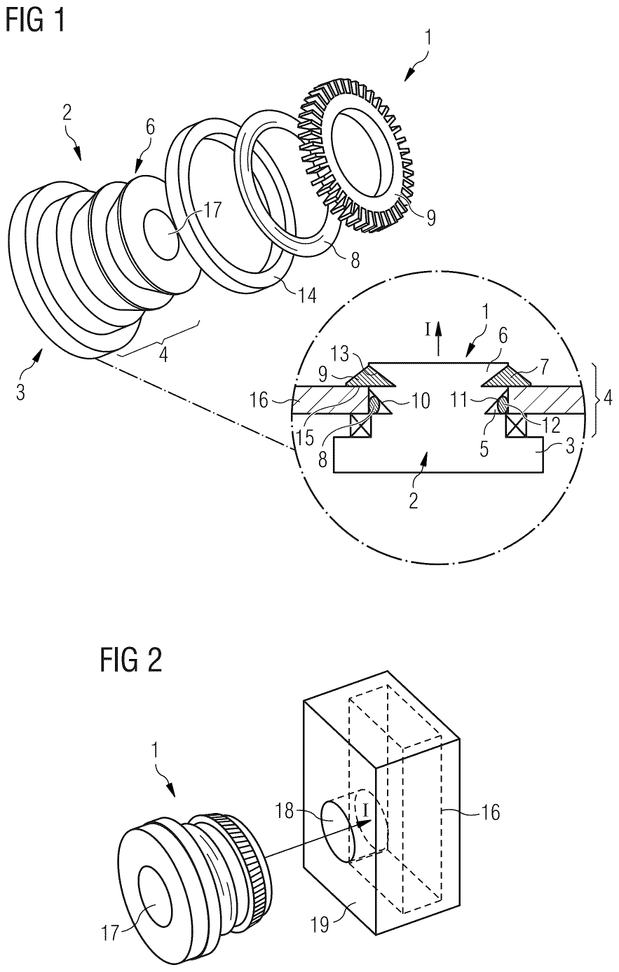

FIG. 1 shows an extended view of a snap-in connector 1 according to the first aspect. The snap-in connector 1 comprises a body 2. The body comprises a base portion 3 and an inserting portion 4. The base portion 3 has a lateral extension which is basically greater than the lateral extension, that is a diameter, of the inserting portion 4. The inserting portion 4 is radially symmetric and comprises a first circumferential groove 5 (also referred to as the first groove 5). The first circumferential groove 5 is spaced apart from the base portion 3 in an inserting direction I of the connector. The inserting portion 4 further comprises an end portion 6. A second circumferential groove 7 is arranged at the inserting portion 4 between the end portion 6 and the first circumferential groove 5. The second circumferential groove 7 is also referred to as the second groove 7.

A first O-ring 8 is accommodated in the first circumferential groove 5. The snap in connector 1 further comprises a radial symmetric locking spring 9. The locking spring 9 is arranged in the second groove 7. The second groove 7 and the locking spring 9 are configured to fit together and to form a positively interlocking connection.

The inserting portion 4 further comprises a collar 10. Collar 10 is a section between the first and second grooves 5,7. Collar 10 may be a radially outward protruding ring surface portion of the inserting portion 4. As shown in the extended view of FIG. 1, the collar 10 is formed by an edge portion 11, that is an apex portion 11 of a first inclined surface portion 12.

The first groove 5 is formed by the first inclined surface portion 12 and configured to accommodate the first O-ring 8. The first inclined surface portion 12 forms a recess in the inserting portion 4. The recess forms the first groove 5.

The second groove 7 is formed by a second inclined surface portion 13 of the inserting portion 4. The second inclined surface portion 13 forms a recess in the body 2 with the side wall oblique with respect to the inserting portion 4.

The snap in connector 1 comprises a second gasket which is a second O-ring 14. The second O-ring 14 has a rectangular cross-section and is arranged at the base portion 3 configured to seal-up in the inserting direction I. A lower surface of the second O-ring 14, that is, a surface of the O-ring facing the base portion 3, is substantially coplanar with the surface of the base portion 3. The dimension of the second O-ring 14 may be such that a distance between the surface of the second O-ring in the inserting direction I and a lower surface 15 of the locking spring 9, that is the surface of the locking spring with a surface normal pointing opposite to the inserting direction I, is smaller than the thickness of a housing 16 in which the snap-in connector 1 is insertable. In an inserted position, both the first O-ring and the second O-ring 8,14 are compressed and hence form a leakproof connection with the housing 16.

The locking spring 9 is a circular spring element which is accommodated in the second groove 7 and held by the second groove 7 in a direction opposite the inserting direction I.

In the inserted position of the snap-in connector 1, the lower surface 15 of the locking spring 9 is coplanar with a wall of the housing 16, particularly wherein the lower surface 15 of the locking spring 9 is in a plane normal to the inserting direction I. The inserting direction I is a direction parallel to a rotation axis of the radial symmetric inserting portion 4. Depending on the form of the second groove 7 the locking spring 9 may be no longer radially compressible after having been inserted into the housing 16. In this way, a non-releasable connection can be established.

In the inserted position as shown in the extended view of FIG. 1 the locking spring 9, that is the lower surface 15 of the locking spring 9 engages behind the housing 16. Together with the second O-ring 14 an axial compression of the housing 16 can be established.

Both the base portion 3 and the inserting portion 4 surround a fluid channel 17. The fluid channel 17 enables the liquid or a fluid to flow through the snap-in connector 1.

FIG. 2 shows a schematic view of the snap in connector 1 before being inserted into an opening 18 of a tube or housing 16. The housing 16 comprises at least one last planar surface 19, wherein the opening 18 is arranged at the planar surface 19. The planar surface 19 is co-planar with the upper surface of the base portion 3 on which the second O-ring 14 is arranged.

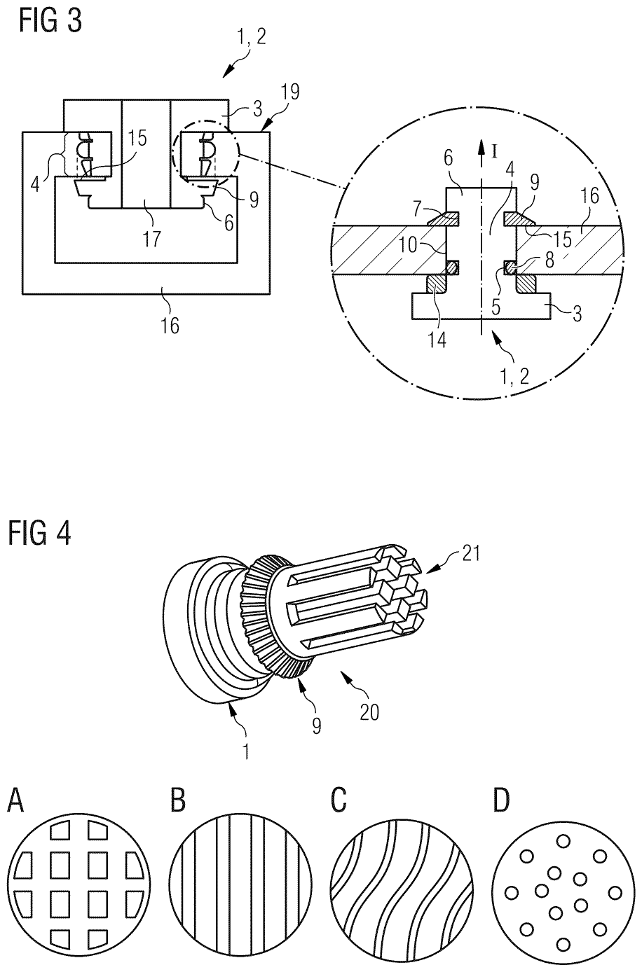

FIG. 3 shows a schematic view of the connector of FIG. 2 being inserted into the opening 18 of the tube or housing 16 in the inserted position. In the extended view of FIG. 3 a further implementation of the inserting portion 4 is shown.

The collar 10 is formed by a radial protrusion having a circumferential surface which is cylindric and wherein the longitudinal axis of the cylindric circumferential surface is parallel to the longitudinal axis of the body 2. The first groove 5 has a substantially rectangular cross-section that is, an inner surface of the first groove 5 is also cylindric and parallel to the longitudinal axis of the body 2. The second groove 7 is spaced apart in the inserting direction from the first groove 5 by the collar 10. A cross-section of the second groove 7 is also rectangular. In this implementation, the locking spring 9 is shown in the inserted position and engages behind the housing 16. Due to the rectangular form of the second groove 7 the locking spring 9 cannot be re-opened by an axial force opposite the inserting direction. The connection between the housing and the snap-in connector 1 is hence non-releasable.

FIG. 4 shows a schematic view of a heat exchanger 20 according to the second aspect of the disclosure. The heat exchanger 20 comprises a snap-in connector 1. The snap-in connector 1 is the snap-in connector 1 of the first aspect of the disclosure as described above. The heat exchanger 20 further comprises a heat exchanger portion 21. The heat exchanger portion 21 is coupled to the end portion 6 of the snap-in connector 1.

The heat exchanger portion 21 comprises protrusions 22 which may be fins or fingers, which are configured to protrude into a flow of a cooling liquid (not shown).

In a first arrangement (A) of the protrusions 22 the heat exchanger portion 21 is obtained by a cylindrical cutout of a periodically and equally arranged scheme of rectangular protrusions.

In a second arrangement (B) the protrusions 22 are formed by a cylindrical cutout of wall-like cooling ribs.

In a third arrangement (C) the protrusions 22 are wall-like cooling ribs having a waveform in the flow direction of the fluid.

In a fourth arrangement (D) the protrusions 22 are needle-shaped and may be regularly or irregularly arranged at the heat exchanger portion 21.

FIG. 5 shows the heat exchanger 20 of FIG. 4 in a position mounted to a semiconductor package 23. The semiconductor package 23 is a surface mount device, SMD. The heat exchanger 20 is attached to an exposed die pad of the semiconductor package 23. Heat produced inside the semiconductor package is conducted to the exposed die pad and further conducted to the base portion 3 and further to the heat exchanger portion 21.

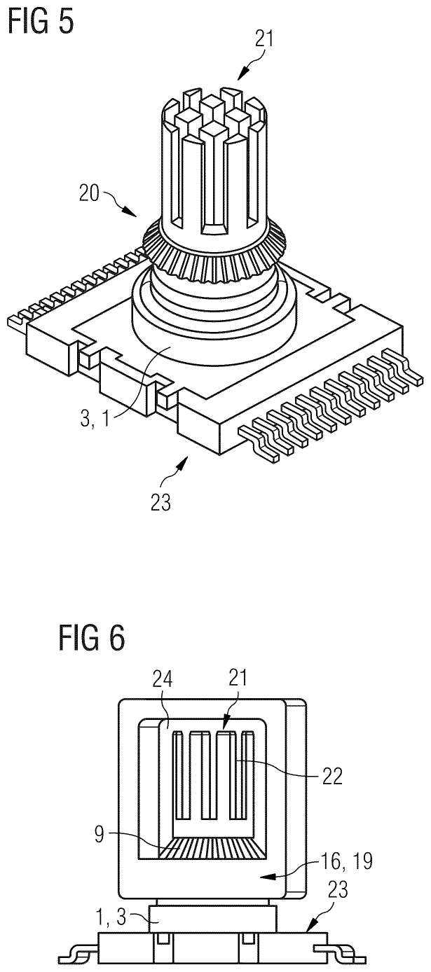

FIG. 6 shows a cross-section of the heat exchanger 20 of FIG. 5 in an inserted position. The heat exchanger 20 is inserted through an opening (not visible) into a housing 16, wherein the housing 16 is a fluid pipe. An interior of the housing 16 forms a liquid channel 24. The protrusions 22 of the heat exchanger portion 21 protrude into the liquid channel 24 and are hence in contact with a cooling liquid which flows through the liquid channel 24. Direct heat transfer into sealed liquid channels 24 is thereby enabled.

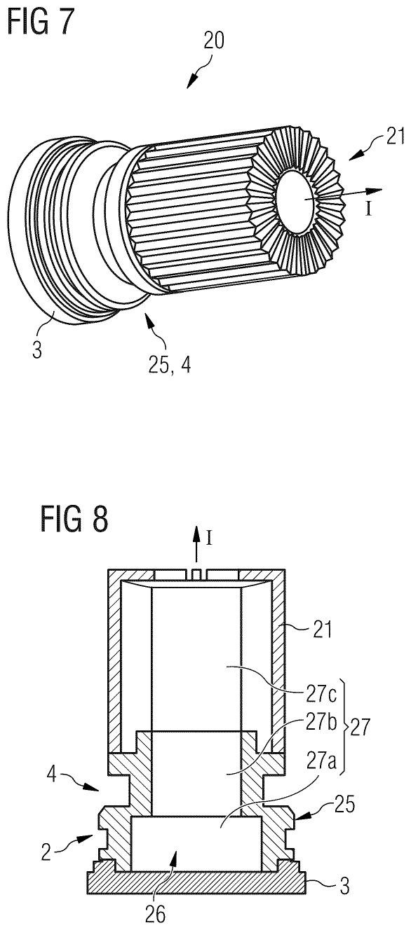

FIG. 7 shows a further implementation of the heat exchanger 20 according to the second aspect of the disclosure. The heat exchanger 20 may both be electrically isolating or electrically non-isolating. In the implementation shown in FIG. 7 the heat exchanger 20 is electrically isolating. The heat exchanger 20 has an isolating portion 25. Isolating portion 25 may be of an electrically long-term stable isolating material, for example glass or ceramic. However other materials are also envisaged. Isolating portion 25 substantially corresponds to inserting portion 4. Isolating portion 25 electrically isolates the base portion 3 from the heat exchanger portion 21.

FIG. 8 shows a cross-sectional view of the heat exchanger 20 of FIG. 7. The inserting portion 4 and the heat exchanger portion 21 comprise a heat transfer portion 26. The inserting portion 4 and the heat exchanger portion 21 surround the heat transfer portion 26. The heat transfer portion 26 is a liquid chamber 27, that is a sealed vapor chamber. The liquid chamber 27 has various sections 27a, 27b, and −27c. The vapor chamber extends along and is concentric with the axis of radial symmetry of the body 2. Liquid chamber 27 is a thermosyphon containing a heat transfer liquid, which is a phase change liquid in general. The phase change liquid may be water or paraffin wax. The liquid chamber 27 may include a wick structure. The heat exchanger portion 21 is thermally coupled to the heat transfer portion 26 in the inserting direction I.

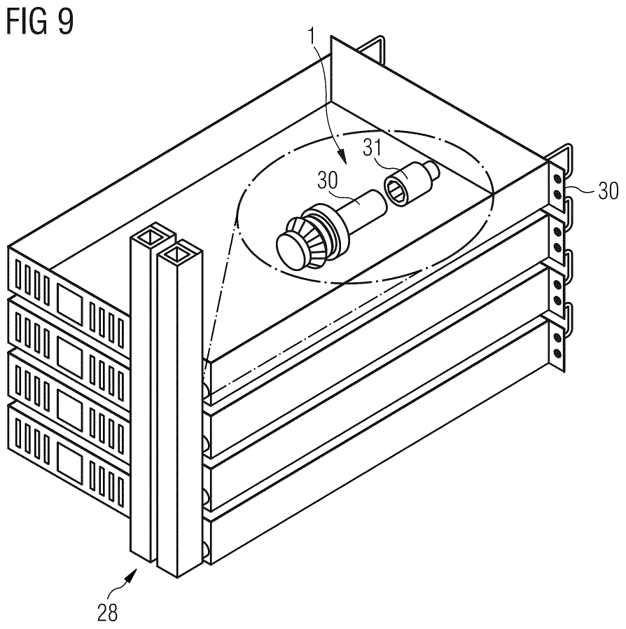

FIG. 9 shows a part of a cooling system comprising the snap-in connector 1. As shown, the system may comprise two fluid pipes 28. The fluid pipes are connected by the snap-in connectors 1 to electronic racks 29. In this configuration, the snap-in connector 1 comprises a shaft portion 30, which is an extended inserting portion 4, to which a sleeve 31 is attachable. The sleeve 31 serves as a spacer between the fluid pipes 28 and the racks 29.

The sleeve 31 comprises the distal end comprising a threaded portion which allows the sleeve to be connected to the racks 29.

### ASPECTS

The following provides an overview of some aspects of the present disclosure:
Aspect 1: A snap-in connector, comprising: a body, the body comprising: a radial-symmetric inserting portion and a base portion; wherein a first circumferential groove is arranged at the radial-symmetric inserting portion spaced apart from the base portion in an inserting direction of the snap-in connector; wherein the radial-symmetric inserting portion comprises an end portion spaced apart from the first circumferential groove in the inserting direction; wherein a second circumferential groove is arranged at the radial-symmetric inserting portion between the end portion and the first circumferential groove; and wherein the snap-in connector further comprises: a first gasket arranged in the first circumferential groove configured to seal-up in a radial direction; and a radial symmetric locking spring accommodated in the second circumferential groove.
Aspect 2: The snap-in connector of Aspect 1, comprising: a collar being spaced apart from the base portion in an inserting direction, particularly wherein the collar comprises a radially outward protruding ring surface portion of the radial-symmetric inserting portion of the body between the first and the second circumferential grooves; and/or a second gasket arranged at the base portion configured to seal-up in the inserting direction.
Aspect 3: The snap-in connector of any of Aspects 1-2, wherein the first circumferential groove is formed by a first inclined surface portion of the radial-symmetric inserting portion, the first inclined surface portion forming a recess in the body with a sidewall oblique with respect to the inserting direction.
Aspect 4: The snap-in connector of any of Aspects 1-3, wherein the second circumferential groove is formed by a second inclined surface portion of the radial-symmetric inserting portion, the second inclined surface portion forming a recess in the body with a sidewall oblique with respect to the inserting direction.
Aspect 5: The snap-in connector of Aspect 2, wherein a distance between a surface of the second gasket in the inserting direction and a lower surface of the radial symmetric locking spring opposite the inserting direction equals a thickness of a housing in which the connector is insertable.
Aspect 6: The snap-in connector of Aspect 5, wherein the second gasket is an elastic element configured to apply a pressure against the housing in an inserted position, that is, that a distance between the surface of the second gasket in the inserting direction and the lower surface of the radial symmetric locking spring opposite the inserting direction is smaller than a thickness of the housing.
Aspect 7: The snap-in connector of Aspect 2, wherein the second gasket is an O-ring with a rectangular cross-section.
Aspect 8: The snap-in connector of Aspect 6, wherein the first gasket is an O-ring of an elastic material and is configured to be compressed, by the housing, in the inserted position of the connector, wherein a diameter of the collar equals a diameter of a bore of the housing in which the connector is insertable, and wherein a diameter of the first gasket is greater than the diameter of the collar in a non-inserted position.
Aspect 9: The snap-in connector of any of Aspects 1-8, wherein the first gasket is an O-ring with a circular cross-section.
Aspect 10: The snap-in connector of any of Aspects 1-9, wherein the radial symmetric locking spring is a circular spring element configured to be accommodated in the second circumferential groove and to be held by the second circumferential groove in at least a direction opposite the inserting direction.
Aspect 11: The snap-in connector of Aspect 6, wherein the radial symmetric locking spring comprises a triangular cross section and wherein the lower surface of the radial symmetric locking spring protrudes radially outward of the second circumferential groove and extends a diameter of the radial-symmetric inserting portion, particularly the collar, wherein the lower surface is configured to engage positively interlocking with a wall of the housing, in the inserted position.
Aspect 12: The snap-in connector of Aspect 5, wherein the lower surface of the radial symmetric locking spring is coplanar with a wall of the housing, particularly wherein the lower surface of the radial symmetric locking spring is in a plane normal to the inserting direction.
Aspect 13: The snap-in connector of any of Aspects 1-12, wherein the base portion is of a cylindric shape and comprises: a diameter greater than the radial-symmetric inserting portion; and a circumferential surface facing in the inserting direction, and which is in a plane normal to the inserting direction.
Aspect 14: The snap-in connector of any of Aspects 1-13, wherein both the radial-symmetric inserting portion and the base portion surround a fluid channel, and wherein the fluid channel extends along and is concentric with an axis of radial symmetry of the body.
Aspect 15: A heat exchanger, comprising: a snap-in connector comprising a base portion and an inserting portion, wherein the base portion is configured to be thermally coupled to a heat source and the inserting portion is configured to interlock with a corresponding opening, wherein the inserting portion comprises an end portion at a distal end of the snap-in connector in an inserting direction; and a heat exchanger portion configured to transfer heat to a fluid, wherein the heat exchanger portion is coupled to the end portion of the snap-in connector, particularly wherein the heat exchanger portion is integrally formed with the end portion.
Aspect 16: The heat exchanger of Aspect 15, wherein the snap-in connector is the snap-in connector formed according to claim 1.
Aspect 17: The heat exchanger of any of Aspects 15-16, wherein the heat exchanger portion comprises at least one protrusion configured to be immersed in the fluid, wherein the at least one protrusion is configured to interact with the fluid in order to generate or avoid turbulences, and wherein the at least one protrusion is a cooling rib or a cooling fin.
Aspect 18: The heat exchanger of Aspect 17, wherein the at least one protrusion includes multiple protrusions that have a waveform in a flow direction of the fluid or are needle shaped or grid shaped.
Aspect 19: The heat exchanger of Aspect 17, wherein at least one of the base portion or the inserting portion comprises a heat transfer portion.
Aspect 20: The heat exchanger of Aspect 19, wherein the base portion is attachable to a heat source, and wherein the heat transfer portion comprises a heat conductive material, to transport heat from the heat source to the heat exchanger portion.
Aspect 21: The heat exchanger of Aspect 19, wherein the inserting portion and the base portion surround the heat transfer portion.
Aspect 22: The heat exchanger of Aspect 21, wherein the heat transfer portion is a sealed vapor chamber containing a transfer liquid, the sealed vapor chamber extending along and being concentric with an axis of radial symmetry of the snap-in connector.
Aspect 23: The heat exchanger of Aspect 19, wherein the heat exchanger portion is thermally coupled to the heat transfer portion in the inserting direction.
Aspect 24: The heat exchanger of Aspect 22, wherein the heat transfer portion is a thermosyphon.
Aspect 25: The snap-in connector of Aspect 1, further comprising: a shaft portion attached to the end portion in the inserting direction; and a sleeve configured to be attachable to the shaft portion and is slidable over the shaft portion.
Aspect 26: The snap-in connector of Aspect 25, wherein the sleeve is a distance sleeve and comprises a threaded distal end configured to connect to a cooling device or a device to be cooled.
Aspect 27: A cooling system for cooling an electronic device, the cooling system comprising: a snap-in connector comprising: a body, the body comprising: a radial-symmetric inserting portion and a base portion; wherein a first circumferential groove is arranged at the radial-symmetric inserting portion spaced apart from the base portion in an inserting direction of the snap-in connector; wherein the radial-symmetric inserting portion comprises an end portion spaced apart from the first circumferential groove in the inserting direction; wherein a second circumferential groove is arranged at the radial-symmetric inserting portion between the end portion and the first circumferential groove; and wherein the snap-in connector further comprises: a first gasket arranged in the first circumferential groove configured to seal-up in a radial direction; and a radial symmetric locking spring accommodated in the second circumferential groove, wherein both the radial-symmetric inserting portion and the base portion surround a fluid channel, and wherein the fluid channel extends along and is concentric with an axis of radial symmetry of the body; and a fluid pipe comprising at least one sidewall with an opening to which the snap-in connector is attachable.
Aspect 28: The cooling system of Aspect 27, wherein the sidewall of the fluid pipe with the opening is coplanar with a circumferential surface of the base portion facing in the inserting direction of the snap-in connector.
Aspect 29: The cooling system of any of Aspects 27-28, further comprising: a shaft portion attached to the end portion in the inserting direction; and a sleeve configured to be attachable to the shaft portion and is slidable over the shaft portion.
Aspect 30: A system configured to perform one or more operations recited in one or more of Aspects 1-29.
Aspect 31: An apparatus comprising means for performing one or more operations recited in one or more of Aspects 1-29.

### List of Reference Signs

1 snap-in connector
2 body
3 base portion
4 inserting portion
5 first circumferential groove
6 end portion
7 second circumferential groove
8 first O-ring
9 locking spring
10 collar
11 Edge/apex portion
12 first inclined surface portion
13 second inclined surface portion
14 second O-ring
15 lower surface of locking spring
16 housing
17 fluid channel
18 opening
19 planar surface
20 heat exchanger
21 heat exchanger portion
22 protrusions
23 Semiconductor package
24 liquid channel
25 isolating portion
26 heat transfer portion
27 liquid chamber
28 fluid pipes
29 racks
30 shaft portion
31 sleeve

1. A snap-in connector, comprising:
a body, the body comprising:
a radial-symmetric inserting portion and a base portion;
wherein a first circumferential groove is arranged at the radial-symmetric inserting portion spaced apart from the base portion in an inserting direction of the snap-in connector;
wherein the radial-symmetric inserting portion comprises an end portion spaced apart from the first circumferential groove in the inserting direction;
wherein a second circumferential groove is arranged at the radial-symmetric inserting portion between the end portion and the first circumferential groove; and
wherein the snap-in connector further comprises:
a first gasket arranged in the first circumferential groove configured to seal-up in a radial direction; and
a radial symmetric locking spring accommodated in the second circumferential groove.

2. The snap-in connector of claim 1, comprising:
a collar being spaced apart from the base portion in an inserting direction, particularly wherein the collar comprises a radially outward protruding ring surface portion of the radial-symmetric inserting portion of the body between the first and the second circumferential grooves; and/or
a second gasket arranged at the base portion configured to seal-up in the inserting direction.

3. The snap-in connector of claim 1, wherein the first circumferential groove is formed by a first inclined surface portion of the radial-symmetric inserting portion, the first inclined surface portion forming a recess in the body with a sidewall oblique with respect to the inserting direction.

4. The snap-in connector of claim 1, wherein the second circumferential groove is formed by a second inclined surface portion of the radial-symmetric inserting portion, the second inclined surface portion forming a recess in the body with a sidewall oblique with respect to the inserting direction.

5. The snap-in connector of claim 2, wherein a distance between a surface of the second gasket in the inserting direction and a lower surface of the radial symmetric locking spring opposite the inserting direction equals a thickness of a housing in which the connector is insertable.

6. The snap-in connector of claim 5, wherein the second gasket is an elastic element configured to apply a pressure against the housing in an inserted position, that is, that a distance between the surface of the second gasket in the inserting direction and the lower surface of the radial symmetric locking spring opposite the inserting direction is smaller than a thickness of the housing.

7. The snap-in connector of claim 2, wherein the second gasket is an O-ring with a rectangular cross-section.

8. The snap-in connector of claim 6, wherein the first gasket is an O-ring of an elastic material and is configured to be compressed, by the housing, in the inserted position of the connector,
wherein a diameter of the collar equals a diameter of a bore of the housing in which the connector is insertable, and
wherein a diameter of the first gasket is greater than the diameter of the collar in a non-inserted position.

9. The snap-in connector of claim 1, wherein the first gasket is an O-ring with a circular cross-section.

10. The snap-in connector of claim 1, wherein the radial symmetric locking spring is a circular spring element configured to be accommodated in the second circumferential groove and to be held by the second circumferential groove in at least a direction opposite the inserting direction.

11. The snap-in connector of claim 6, wherein the radial symmetric locking spring comprises a triangular cross section and wherein the lower surface of the radial symmetric locking spring protrudes radially outward of the second circumferential groove and extends a diameter of the radial-symmetric inserting portion, particularly the collar, wherein the lower surface is configured to engage positively interlocking with a wall of the housing, in the inserted position.

12. The snap-in connector of claim 5, wherein the lower surface of the radial symmetric locking spring is coplanar with a wall of the housing, particularly wherein the lower surface of the radial symmetric locking spring is in a plane normal to the inserting direction.

13. The snap-in connector of claim 1, wherein the base portion is of a cylindric shape and comprises:
a diameter greater than the radial-symmetric inserting portion; and
a circumferential surface facing in the inserting direction, and which is in a plane normal to the inserting direction.

14. The snap-in connector of claim 1, wherein both the radial-symmetric inserting portion and the base portion surround a fluid channel, and
wherein the fluid channel extends along and is concentric with an axis of radial symmetry of the body.

15. A heat exchanger, comprising:
a snap-in connector comprising a base portion and an inserting portion, wherein the base portion is configured to be thermally coupled to a heat source and the inserting portion is configured to interlock with a corresponding opening, wherein the inserting portion comprises an end portion at a distal end of the snap-in connector in an inserting direction; and
a heat exchanger portion configured to transfer heat to a fluid, wherein the heat exchanger portion is coupled to the end portion of the snap-in connector, particularly wherein the heat exchanger portion is integrally formed with the end portion.

16. The heat exchanger of claim 15, wherein the snap-in connector is the snap-in connector formed according to claim 1.

17. The heat exchanger of claim 15, wherein the heat exchanger portion comprises at least one protrusion configured to be immersed in the fluid,
wherein the at least one protrusion is configured to interact with the fluid in order to generate or avoid turbulences, and
wherein the at least one protrusion is a cooling rib or a cooling fin.

18. The heat exchanger of claim 17, wherein the at least one protrusion includes multiple protrusions that have a waveform in a flow direction of the fluid or are needle shaped or grid shaped.

19. The heat exchanger of claim 17, wherein at least one of the base portion or the inserting portion comprises a heat transfer portion.

20. The heat exchanger of claim 19, wherein the base portion is attachable to a heat source, and
wherein the heat transfer portion comprises a heat conductive material, to transport heat from the heat source to the heat exchanger portion.

21. The heat exchanger of claim 19, wherein the inserting portion and the base portion surround the heat transfer portion.

22. The heat exchanger of claim 21, wherein the heat transfer portion is a sealed vapor chamber containing a transfer liquid, the sealed vapor chamber extending along and being concentric with an axis of radial symmetry of the snap-in connector.

23. The heat exchanger of claim 19, wherein the heat exchanger portion is thermally coupled to the heat transfer portion in the inserting direction.

24. The heat exchanger of claim 22, wherein the heat transfer portion is a thermosyphon.

25. The snap-in connector of claim 1, further comprising:
a shaft portion attached to the end portion in the inserting direction; and
a sleeve configured to be attachable to the shaft portion and is slidable over the shaft portion.

26. The snap-in connector of claim 25, wherein the sleeve is a distance sleeve and comprises a threaded distal end configured to connect to a cooling device or a device to be cooled.

27. A cooling system for cooling an electronic device, the cooling system comprising:
a snap-in connector comprising:
a body, the body comprising:
a radial-symmetric inserting portion and a base portion;
wherein a first circumferential groove is arranged at the radial-symmetric inserting portion spaced apart from the base portion in an inserting direction of the snap-in connector;
wherein the radial-symmetric inserting portion comprises an end portion spaced apart from the first circumferential groove in the inserting direction;
wherein a second circumferential groove is arranged at the radial-symmetric inserting portion between the end portion and the first circumferential groove; and
wherein the snap-in connector further comprises:
a first gasket arranged in the first circumferential groove configured to seal-up in a radial direction; and
a radial symmetric locking spring accommodated in the second circumferential groove,
wherein both the radial-symmetric inserting portion and the base portion surround a fluid channel, and
wherein the fluid channel extends along and is concentric with an axis of radial symmetry of the body; and
a fluid pipe comprising at least one sidewall with an opening to which the snap-in connector is attachable.

28. The cooling system of claim 27, wherein the sidewall of the fluid pipe with the opening is coplanar with a circumferential surface of the base portion facing in the inserting direction of the snap-in connector.

29. The cooling system of claim 27, further comprising:
a shaft portion attached to the end portion in the inserting direction; and
a sleeve configured to be attachable to the shaft portion and is slidable over the shaft portion.
